(19) United States
(12) Patent Application Publication
(10) Pub. No.: US 2026/0190831 A1
(43) Pub. Date: Jul. 2, 2026

(54) DISPLAY DEVICE

(71) Applicant: LG Display Co., Ltd., Seoul (KR)

(72) Inventors: Jeongbeom LEE, Seoul (KR); Jungeun LEE, Seoul (KR); HwanKeon LEE, Gimpo-si (KR); Junhyeok LEE, Seoul (KR)

(73) Assignee: LG Display Co., Ltd., Seoul (KR)

(21) Appl. No.: 19/388,874

(22) Filed: Nov. 13, 2025

(30) Foreign Application Priority Data
Dec. 27, 2024 (KR) 10-2024-019877

(51) Int. Cl. H10K 59/80

(52) U.S. Cl. CPC H10K 59/8792

(57) ABSTRACT

A display device includes a substrate having an active area and a non-active area, a plurality of light emitting diodes on the substrate, and an encapsulation layer covering the light emitting diodes. A touch sensing unit including a plurality of touch electrodes is disposed on the encapsulation layer. A plurality of organic dye patterns is disposed on the touch sensing unit so as to overlap emission areas of the light emitting diodes, each organic dye pattern having a bottom surface larger than a top surface. A black matrix is arranged to expose the top surfaces of the organic dye patterns. The configuration refracts light from the side surfaces toward the top surfaces of the organic dye patterns, allowing a portion of the emitted light to be transmitted through the openings of the black matrix and thereby improving the luminous efficiency of the display device.

### CROSS-REFERENCE TO RELATED APPLICATIONS

This application claims the priority of and benefits to Korean Patent Application No. 10-2024-0198774 filed on December 27, 2024, in the Korean Intellectual Property Office, the disclosure of which is incorporated herein by reference in its entirety for all purposes, as if fully set forth herein.

### BACKGROUND

### Technical Field

The present disclosure relates to a display device and method for manufacturing the same, and more particularly, for example, without limitation, to a display device and method for manufacturing the same which improves a luminous efficiency.

### Description of the Related Art

As it enters the information era, a field of a display device which visually expresses electrical information signals has been rapidly developed and studies are continued to improve performances of various display devices, such as a thin-thickness, a light weight, and low power consumption.

A representative display device may include a liquid crystal display device (LCD), a field emission display device (FED), an electro-wetting display device (EWD), and an organic light emitting display device (OLED), without being limited thereto.

An electroluminescent display device which is represented by an organic light emitting display device is a self-emitting display device so that a separate light source is not necessary, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, and a contrast ratio (CR), it is expected to be utilized in various fields.

The description provided in the background section should not be assumed to be prior art merely because it is mentioned in or associated with the background section. The background section may include information that describes one or more aspects of the subject technology.

### BRIEF SUMMARY

The present disclosure relates to a display device, particularly an OLED type display, that improves luminous efficiency, simplifies manufacturing, and supports narrow viewing angles suitable for privacy or virtual reality applications. The structure includes a plurality of organic dye patterns positioned above the encapsulation layer, each having a larger bottom surface and a smaller top surface with curved sides. This configuration guides emitted light upward so that even light directed toward the black matrix is partially refracted through the opening rather than absorbed, thereby increasing overall luminous efficiency.

A black matrix is arranged on the same plane as the dye patterns, covering their sides and filling the spaces between them. The matrix has openings smaller than the emission areas to narrow the viewing angle and may include grooves that enhance black visibility when the display is off. The dye patterns and the black matrix are formed and planarized together to maintain a flat surface and reduce light leakage, which removes the need for a separate polarizing plate and allows for a thinner and higher contrast display.

Manufacturing is achieved through a maskless inkjet deposition and chemical mechanical polishing process, which enables precise control over thickness, transmittance, and reflectance. This method reduces production cost and time while allowing flexibility in adjusting optical performance. The resulting structure provides improved brightness, reduced reflection, and efficient fabrication suitable for advanced display panels.

Various embodiments of the present disclosure provide a display device which is capable of improving a luminous efficiency.

Various embodiments of the present disclosure provide a display device which reduces a cost and a time of a manufacturing process of a display device.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate including an active area in which the plurality of sub pixels is disposed and a non-active area which encloses the active area; a plurality of light emitting diodes which is disposed in the plurality of sub pixels on the substrate; an encapsulation unit disposed so as to cover the plurality of light emitting diodes; a touch sensing unit which is disposed on the encapsulation unit and includes a plurality of touch electrodes, a plurality of organic dye patterns which is disposed on the touch sensing unit so as to overlap emission areas of the plurality of light emitting diodes and has bottom surfaces larger than top surfaces; and a black matrix which exposes the top surfaces of the plurality of organic dye patterns.

According to another aspect of the present disclosure, a display device includes: a substrate; a plurality of light emitting diodes disposed on the substrate; an encapsulation unit disposed so as to cover the plurality of light emitting diodes; a touch sensing unit which is disposed on the encapsulation unit and includes a plurality of touch electrodes, a black matrix which is disposed on the touch sensing unit and includes an opening overlapping emission areas of the plurality of light emitting diodes; and a plurality of organic dye patterns which is disposed between the black matrices and has bottom surfaces larger than the opening of the black matrix, top surfaces having the same size as the opening of the black matrix, and side surfaces which connect the top surfaces and the bottom surfaces and have a curved shape.

Other detailed matters of the exemplary embodiments are included in the detailed description and the drawings.

According to the present disclosure, in a display device, a size of the opening of the black matrix is configured to be smaller than an emission area of the plurality of light emitting diodes so that it is advantageously applied to a display device which applies a switchable privacy mode or a display device in which a narrow viewing angle is desirable, such as an external display of a VR device.

According to the present disclosure, in the display device, even though some of light emitted from the plurality of light emitting diodes is directed to a direction overlapping a black matrix, not all emitted light is absorbed by the black matrix, but some of light is emitted through the opening along a light path, thereby improving a luminous efficiency of the display device.

According to the present disclosure, in the display device, a plurality of organic dye patterns is formed by an application process, such as inkjet to omit a mask process so that process optimization, such as reduced cost and time for a manufacturing process, may be achieved.

The effects according to the present disclosure are not limited to the contents exemplified above, and more various effects are included in the present specification.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other aspects, features and other advantages of the present disclosure will be more clearly understood from the following detailed description taken in conjunction with the accompanying drawings, in which:

FIG. 1 is a block diagram for explaining a display device according to an exemplary embodiment of the present disclosure;

FIG. 2 is a view schematically illustrating a circuit configuration of a sub pixel according to exemplary embodiments of the present disclosure;

FIG. 3 is a cross-sectional view taken along III-III′ of FIG. 1;

FIG. 4 is a schematic cross-sectional view of a display device according to another exemplary embodiment of the present disclosure; and

FIGS. 5A to 5D are schematic diagrams illustrating a manufacturing method of a display device according to another exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated. The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

In the description of the various embodiments of the present disclosure, where positional relationships are described, for example, when a position relation between two parts is described as, for example, “on,” “over,” “under,” and “next,” or the like, one or more other parts may be located between the two parts unless a more limiting term, such as “just” or “direct(ly)” is used. For example, where an element or layer is disposed “on” another element or layer, a third layer or element may be interposed therebetween.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

The terms, such as “below,” “lower,” “above,” “upper” and the like, may be used herein to describe a relationship between element item(s) as illustrated in the drawings. It will be understood that the terms are spatially relative and based on the orientation depicted in the drawings.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various exemplary embodiments of the present disclosure will be described in detail with reference to the accompanying drawings.

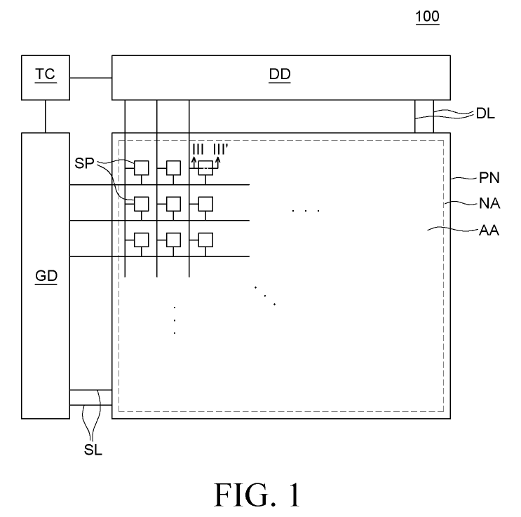

FIG. 1 is a block diagram for explaining a display device according to an exemplary embodiment of the present disclosure. FIG. 1 is a schematic diagram of a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto. As an example, two or more gate drivers GD may be disposed to be spaced apart from one side of the display panel PN, without being limited thereto. As an example, one or more gate drivers GD may be disposed to be spaced apart from each of both sides of the display panel PN, without being limited thereto.

The data driver DD supplies a data voltage to a plurality of data lines DL according to a plurality of data control signals and image data supplied from the timing controller TC. The data driver DD converts the image data into a data voltage using a reference gamma voltage and may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. Further, the timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP may be formed at intersections of the scan lines SL and the data lines DL.

In the display panel PN, an active area AA and a non-active area NA may be defined.

The active area AA is an area in which images are displayed in the display device 100. In the active area AA, a plurality of sub pixels SP which configures a plurality of pixels and a pixel circuit for driving the plurality of sub pixels SP may be disposed. The plurality of sub pixels SP is a minimum unit which configures the active area AA and n sub pixels SP form one pixel. As an example, n may be an integral number equal to or greater than one. In each of the plurality of sub pixels SP, a thin film transistor for driving the plurality of light emitting diodes is disposed so that the plurality of sub pixels SP may independently emit light. For example, the plurality of sub pixels may include a first sub pixel, a second sub pixel, and a third sub pixel which emit different color light, without being limited thereto. As an example, the plurality of sub pixels may include two, four or more sub pixels which emit different color light. For example, the first sub pixel is a red sub pixel which emits red light, the second sub pixel is a green sub pixel which emits green light, and the third sub pixel is a blue sub pixel which emits blue light, but the present disclosure is not limited thereto. As an example, a sub pixel which emits white light may be further included. As an example, a sub pixel which emits light of other colors such as cyan, magenta, or yellow, etc., may be alternatively or additionally included.

The plurality of light emitting diodes may be defined in different manners depending on the type of the display panel PN. For example, when the display panel PN is an organic light emitting display panel, the light emitting diode may be an organic light emitting diode.

In the active area AA, a plurality of signal lines which transmits various signals to the plurality of sub pixels SP is disposed. For example, the plurality of signal lines may include a plurality of data lines DL which supplies a data voltage to each of the plurality of sub pixels SP and a plurality of scan lines SL which supplies a scan signal to each of the plurality of sub pixels SP. The plurality of scan lines SL extends along one direction in the active area AA to be connected to the plurality of sub pixels SP and the plurality of data lines DL extends along a direction different from the one direction in the active area AA to be connected to the plurality of sub pixels SP. In addition, in the active area AA, a low potential power line and a high potential power line may be further disposed, but are not limited thereto.

The non-active area NA is an area where images are not displayed so that the non-active area NA may be defined as an area extending from the active area AA. As an example, the non-active area NA may fully or partially surround the active area AA, without being limited thereto. As an example, the non-display area NDA may be at least partially or entirely invisible from a front side of the display panel PN, for example, by being bent toward a rear side of the display panel PN, without being limited thereto. As another example, the entire non- display area NA may be flat. In the non-active area NA, a link line which transmits a signal to the sub pixel SP of the active area AA, a pad electrode, or a driving IC, such as a gate driver IC or a data driver IC, may be disposed.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. As another example, the gate driver GD may be mounted separately in a separate panel or film and connected to the display panel PN (e.g., to the non-active area NA), for example, in a tape automated bonding (TAB) method, a chip on glass (COG) method, a chip on panel (COP) method, or a chip on film (COF) method, without being limited thereto.

For example, the data driver DD and the timing controller TC are formed in separate flexible film and printed circuit board. For example, the display panel PN is electrically connected to the data driver DD and the timing controller TC by bonding the flexible film and the printed circuit board to the pad electrode formed in the non-active area NA of the display panel PN, without being limited thereto.

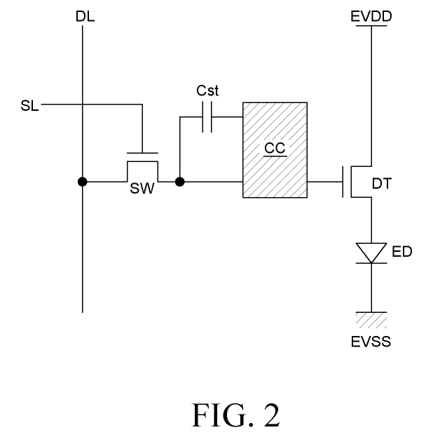

FIG. 2 is a view schematically illustrating a circuit configuration of a sub pixel according to an exemplary embodiment of the present disclosure.

Referring to FIG. 2, in one sub pixel, as an example, a switching transistor SW, a driving transistor DT, a capacitor Cₛₜ, a compensation circuit CC, and an organic light emitting diode ED may be included, without being limited thereto. As an example, at least one of the above-mentioned components (e.g., the compensation circuit CC) may be omitted depending on the design. As an example, one or more transistors or one or more capacitors may be additionally included, without being limited thereto.

For example, the switching transistor ST may perform a switching operation such that a data signal supplied through the data line DL is stored in a capacitor Cₛₜ as a data voltage in response to a scan signal supplied through the scan line SL. Further, for example, the driving transistor DT may operate to flow a driving current between a high potential power line EVDD and a low potential power line EVSS in response to a data voltage stored in the capacitor Cₛₜ. Further, the organic light emitting diode ED may operate to emit light in accordance with a driving current formed by the driving transistor DT.

The compensation circuit CC is a circuit added in the sub pixel to compensate for a threshold voltage of the driving transistor DT. The compensation circuit CC may be configured by one or more transistors. A configuration of the compensation circuit CC may vary depending on an external compensating method.

The sub pixel illustrated in FIG. 2 is configured by a 2T (transistor) 1C (capacitor) structure including a switching transistor ST, a driving transistor DT, a capacitor Cₛₜ, and a light emitting diode ED. When the compensation circuit 135 is added, the sub pixel may be configured in various forms, such as 3T1C, 4T2C, 5T2C, 6T1C, 6T2C, 7T1C, and 7T2C.

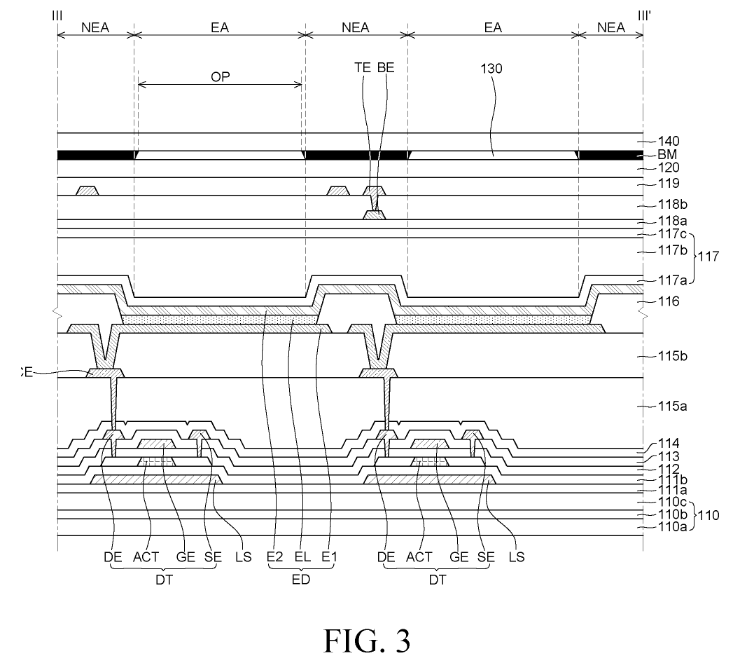

FIG. 3 is a cross-sectional view taken along III-III′ of FIG. 1. In FIG. 3, for the convenience of description, a component included in each of two adjacent sub pixels SP disposed in the active area AA is illustrated.

Referring to FIG. 3, the substrate 110 is a configuration for supporting various components included in the display device 100 and may be formed of, for example, an insulating material, without being limited thereto. As an example, the substrate 110 may include a single layer or multiple layers. As an example, the substrate 110 may include a first substrate 110a, an insulating layer 110b, and a second substrate 110c, without being limited thereto. The insulating layer 110b may be disposed between the first substrate 110a and the second substrate 110c. As described above, the substrate 110 is configured by the first substrate 110a, the second substrate 110c, and the insulating layer 110b to suppress the moisture permeation. For example, the first substrate 110a and the second substrate 110c may be polyimide (PI) substrates, without being limited thereto.

A first buffer layer 111a is disposed on the substrate 110. The first buffer layer 111a reduces permeation of moisture, oxygen, or impurities through the substrate 110. For example, the first buffer layer 111a may be configured by a single layer, a double layer or a multiple layer of silicon oxide (SiOx) or silicon nitride (SiNx), but is not limited thereto. As an example, the first buffer layer 111a may be omitted depending on the design.

A light shielding layer LS is disposed in each of the plurality of sub pixels on the first buffer layer 111a. The light shielding layer LS blocks light incident onto an active layer ACT of the driving transistor DT to be described below from a lower portion the substrate 110. Light which is incident onto the active layer ACT of the driving transistor DT is blocked by the light shielding layer LS to reduce or minimize a leakage current. As an example, the light shielding layer LS may at least partially overlap the active layer ACT of the driving transistor DT, without being limited thereto. As an example, the light shielding layer LS may at least partially overlap the channel region of the active layer ACT of the driving transistor DT, without being limited thereto. As an example, the light shielding layer LS may be floated or be supplied with certain potential, without being limited thereto. As an example, the light shielding layer LS may be omitted depending on the design.

A second buffer layer 111b is disposed on the substrate 110 and the light shielding layer LS. The second buffer layer 111b may reduce permeation of moisture or impurities through the substrate 110. For example, the second buffer layer 111b may be configured by a single layer, a double layer or a multiple layer of silicon oxide (SiOx) or silicon nitride (SiNx), but is not limited thereto. However, the second buffer layer 111b may be omitted depending on a type of substrate 110 or a type of transistor, but is not limited thereto.

A driving transistor DT of each of the plurality of sub pixels SP may be disposed on the second buffer layer 111b, without being limited thereto. The driving transistor DT is a transistor which controls a driving current supplied to the light emitting diode ED.

The driving transistor DT includes an active layer ACT, a gate electrode GE, a source electrode SE, and a drain electrode DE.

The active layer ACT of the driving transistor DT is disposed on the second buffer layer 111b. For example, the active layer ACT may be formed of polysilicon (p-Si), amorphous silicon (a-Si), oxide semiconductor, compound semiconductor, or organic semiconductor, etc., but is not limited thereto.

A gate insulating layer 112 may be disposed on the active layer ACT. The gate insulating layer 112 is an insulating layer which insulates the active layer ACT from the gate electrode GE and may be configured by a single layer a double layer, or a multiple layer of silicon oxide (SiOx) or silicon nitride (SiNx), without being limited thereto.

Further, the gate electrode GE of the driving transistor DT may be disposed on the gate insulating layer 112. The gate electrode GE is disposed on the gate insulating layer 112 so as to overlap the active layer ACT. The gate electrode GE may be formed of various conductive materials, for example, magnesium (Mg), aluminum (Al), nickel (Ni), chrome (Cr), molybdenum (Mo), tungsten (W), gold (Au), or an alloy thereof, but is not limited thereto.

An interlayer insulating layer 113 may be disposed while covering the gate electrode GE. The interlayer insulating layer 113 is an insulating layer which protects components below the interlayer insulating layer 113 and may be configured by a single layer, a double layer or a multiple layer of silicon oxide (SiOx) or silicon nitride (SiNx), but is not limited thereto.

As an example, the source electrode SE and the drain electrode DE of the driving transistor DT may be disposed on the interlayer insulating layer 113, without being limited thereto.

As an example, the source electrode SE and the drain electrode DE may be connected to one side and the other side of the active layer ACT through contact holes provided in the interlayer insulating layer 113 and the gate insulating layer 112. The source electrode SE and the drain electrode DE may be formed of various conductive materials, for example, magnesium (Mg), aluminum (Al), nickel (Ni), chrome (Cr), molybdenum (Mo), tungsten (W), gold (Au), or an alloy thereof, but is not limited thereto.

A part of the active layer ACT which overlaps the gate electrode GE is a channel region. One of the source electrode SE and the drain electrode DE is connected to one side of the channel region in the active layer ACT and the other one is connected to the other side of the channel region in the active layer ACT.

As an example, a passivation layer 114 may be disposed on the source electrode SE and the drain electrode DE. The passivation layer 114 is provided to protect the driving transistor DT and may be formed of an inorganic layer, for example, silicon oxide (SiOx), silicon nitride (SiNx), or a double layer or a multiple layer thereof.

A first planarization layer 115a may be disposed on the passivation layer 114. The first planarization layer 115a may protect the driving transistor DT and planarize an upper portion of the driving transistor DT. The first planarization layer 115a may be configured by a single layer, a double layer, or a multiple layer and for example, may be formed of a photoresist or an acrylic-based organic material, but is not limited thereto.

A connection electrode CE may be disposed on the first planarization layer 115a.

The connection electrode CE may be connected to one of the source electrode SE and the drain electrode DE through a contact hole provided in the first planarization layer 115a.

A second planarization layer 115b may be disposed on the connection electrode CE. The second planarization layer 115b may be formed of the same material as, or a different material from the first planarization layer 115a, without being limited thereto. Embodiments are not limited thereto. As an example, the connection electrode CE may be omitted depending on the design. As an example, if the connection electrode CE is omitted, one of the first planarization layer 115a and the second planarization layer 115b may be omitted, without being limited thereto.

A light emitting diode ED including a first electrode E1, an organic layer EL, and a second electrode E2 may be disposed on the second planarization layer 115b.

Hereinafter, a laminated structure of the light emitting diode ED will be described in detail.

The first electrode E1 may be disposed on the second planarization layer 115b. At this time, the first electrode E1 may be electrically connected to the connection electrode CE through a contact hole provided in the second planarization layer 115b. The first electrode E1 is formed of a conductive material, such as a metallic material, without being limited thereto.

For example, when the display device 100 is a top emission type in which light emitted from the light emitting diode ED is emitted above the substrate 110 on which the light emitting diode ED is disposed, the first electrode E1 may include a transparent conductive layer and a reflective layer, without being limited thereto. The transparent conductive layer may be formed of transparent conductive oxide, such as ITO or IZO and the reflective layer may be formed of silver (Ag), aluminum (Al), gold (Au), molybdenum (Mo), tungsten (W), chrome (Cr), or an alloy thereof, without being limited thereto.

The bank 116 is disposed while covering an end of the first electrode E1 to define an emission area. A part of the bank 116 corresponding to an emission area of the sub pixel SP may be open. A part of the first electrode E1 may be exposed through the open part of the bank 116 (hereinafter, referred to as an open area). At this time, the bank 116 may be formed of an inorganic insulating material, such as silicon nitride (SiNx) or silicon oxide (SiOx), or an organic insulating material, such as benzocyclobutene-based resin, acrylic-based resin or imide-based resin, but is not limited thereto.

The bank 116 may be configured by a black bank 116 including a light absorption material. For example, the light absorption material may include carbon or black ink, without being limited thereto. The black bank 116 suppresses light emitted from the light emitting diode ED from being directed to the side surface to suppress color mixtures between adjacent sub pixels SP and suppress external light reflection. Further, even though a polarization layer is not disposed, a light leakage defect may be suppressed.

An organic layer EL may be disposed on the bank 116. Therefore, the organic layer EL may be disposed on the first electrode E1 exposed through the open area of the bank 116. As an example, the organic layer EL may be continued on the top surface of the bank 116, or may be disconnected on the top surface of the bank 116, without being limited thereto.

The organic layer EL is a layer which emits specific color light and may have a structure which is separated for every sub pixel SP. For example, an organic layer EL disposed in a sub pixel SP which emits red light includes an organic layer which emits red light. An organic layer EL disposed in a sub pixel SP which emits green light includes an organic layer which emits green light and an organic layer EL disposed in a sub pixel SP which emits blue light includes an organic layer which emits blue light. Organic layers EL disposed in the sub pixel SP which emits red light, the sub pixel SP which emits green light, and the sub pixel SP which emits blue light may be separately disposed.

The second electrode E2 may be disposed on the organic layer EL and the bank 116.

The light emitting diode ED may be formed by the first electrode E1, the organic layer EL, and the second electrode E2. The organic layer EL may include a plurality of organic material layers.

An encapsulation unit 117 may be located above the above-described light emitting diode ED.

The encapsulation unit 117 may have a single layer structure or a multi-layered structure. For example, the encapsulation unit 117 may include a first encapsulation layer 117a, a second encapsulation layer 117b, and a third encapsulation layer 117c.

At this time, the first encapsulation layer 117a and the third encapsulation layer 117c are configured by inorganic layers and the second encapsulation layer 117b is configured by an organic layer, without being limited thereto. Among the first encapsulation layer 117a, the second encapsulation layer 117b, and the third encapsulation layer 117c, the second encapsulation layer 117b is the thickest and may serve as a planarization layer, without being limited thereto.

The first encapsulation layer 117a is disposed on the second electrode E2 and may be disposed to be the most adjacent to the light emitting diode ED. As an example, the first encapsulation layer 117a may be formed of an inorganic insulating material for which low-temperature deposition may be performed. For example, the first encapsulation layer 117a may be configured by silicon nitride (SiNx), silicon oxide (SiOx), silicon oxynitride (SiON), or aluminum oxide (Al₂O₃), without being limited thereto. The first encapsulation layer 117a is deposited under a low temperature atmosphere so that during the deposition process, the damage of the organic layer EL including an organic material which is vulnerable to the high temperature atmosphere may be suppressed.

The second encapsulation layer 117b may be formed to have a smaller area than that of the first encapsulation layer 117a, without being limited thereto. In this case, the second encapsulation layer 117b may be formed to expose both ends of the first encapsulation layer 117a. The second encapsulation layer 117b may serve as a buffer which alleviates stress between the layers and serve to enhance planarization performance.

For example, the second encapsulation layer 117b may be formed of an organic insulating material, such as acrylic resin, epoxy resin, polyimide, polyethylene, or silicon oxy carbon (SiOC), without being limited thereto. For example, the second encapsulation layer 117b may be formed by an inkjet method, but is not limited thereto.

The third encapsulation layer 117c may be formed above the substrate 110 on which the second encapsulation layer 117b may be formed so as to cover upper surfaces and side surfaces of the second encapsulation layer 117b and the first encapsulation layer 117a, without being limited thereto. At this time, the third encapsulation layer 117c may reduce, minimize or block the permeation of external moisture or oxygen into the first encapsulation layer 117a and the second encapsulation layer 117b. For example, the third encapsulation layer 117c may be configured by an inorganic insulating material, such as silicon nitride (SiNx), silicon oxide (SiOx), silicon oxynitride (SiON), or aluminum oxide (Al₂O₃), without being limited thereto.

As an example, a touch sensing unit may be disposed above the above-described encapsulation unit 117.

Specifically, the touch sensing unit may include a touch buffer layer 118a disposed on the encapsulation unit 117, a bridge electrode BE disposed on the touch buffer layer 118a, a touch interlayer insulating layer 118b disposed on the touch buffer layer 118a and the bridge electrode BE, and a plurality of touch electrodes TE disposed on the touch interlayer insulating layer 118b. Although it is illustrated and described that the bridge electrode BE is disposed under the touch electrodes TE, embodiments are not limited thereto. As an example, the bridge electrode BE may be disposed above the touch electrodes TE. As an example, the touch sensing unit may be omitted depending on the design.

The touch buffer layer 118a may block a chemical solution which is used during a manufacturing process of touch electrodes formed on the touch buffer layer 118a, such as a developer or an etchant, or external moisture or foreign materials from permeating to the light emitting diode.

The plurality of touch electrodes TE may include a plurality of first touch electrodes extending in a first direction and a plurality of second touch electrodes extending in a second direction intersecting the first direction, without being limited thereto.

For example, the plurality of first touch electrodes and the plurality of second touch electrodes may be disposed on the same layer. However, in the intersecting areas of the plurality of first touch electrodes and the plurality of second touch electrodes, the plurality of second touch electrodes is separately disposed and the plurality of separated second touch electrodes may be connected by the bridge electrode BE. The touch interlayer insulating layer 118b may be disposed between the plurality of second touch electrodes and the bridge electrode BE.

The first protection layer 119 may be disposed so as to cover the touch sensing unit. The first protection layer 119 may be configured by an organic insulating layer, without being limited thereto. The first protection layer 119 protects a touch sensing unit and may planarize an upper portion thereof. Further, the step on the top layer of the display device 100 is suppressed by the first protection layer 119 to further improve the visibility of the display device 100.

A third buffer layer 120 may be disposed on the first protection layer 119. The third buffer layer 120 reduces permeation of moisture, oxygen, or impurities through an upper portion of the display device 100. For example, the third buffer layer 120 may be configured by a single layer a double layer, or a multiple layer of silicon oxide (SiOx) or silicon nitride (SiNx), but is not limited thereto.

A black matrix BM may be disposed on the third buffer layer 120. For example, the black matrix BM may be provided in the form of an integrated mesh type so as to overlap the non-emission area NEA of the plurality of light emitting diodes ED, but is not limited thereto.

The black matrix BM may include a light absorption material which absorbs a visible wavelength band. As an example, the black matrix BM may be a kind of a light emitting member, without being limited thereto. For example, the black matrix BM may be configured by a material which may be processed at a low temperature of approximately 100C or lower, and desirably approximately 85C or lower, without being limited thereto. When the black matrix BM may be configured by a material for which low-temperature process is possible, a thermal damage of the light emitting diode ED caused by the formation of the black matrix BM may be reduced or minimized.

The black matrix BM may include an opening OP which overlaps an emission area EA of the plurality of light emitting diodes ED. A top surface of the plurality of organic dye patterns 130 to be described below may be exposed through the opening OP. For example, if it is applied to a display device 100 which applies a switchable privacy mode or a display device 100 in which a narrow viewing angle is desirable, such as an external display of a VR device, a size of the opening OP of the black matrix BM, for example, a width of the opening OP of the black matrix BM may be smaller than the emission areas EA of the plurality of light emitting diodes ED. In this case, the size of the opening OP of the black matrix BM is reduced to reduce reflectance in the non-emission area NEA.

The plurality of organic dye patterns 130 may be disposed between the black matrices BM. For example, the plurality of organic dye patterns 130 and the black matrix BM are located on the same plane. As an example, the plurality of organic dye patterns 130 and the black matrix BM may have the same thickness, such that the top surface of the plurality of organic dye patterns 130 may be aligned with the top surface of the black matrix BM, without being limited thereto. As an example, the plurality of organic dye patterns 130 may be in contact with the black matrix BM laterally.

As an example, the plurality of organic dye patterns 130 may include a colorant, such as dye or pigment and a monomer, without being limited thereto.

The plurality of organic dye patterns 130 may be formed in each emission area EA of the plurality of sub pixels SP, by an application process, such as inkjet or photo.

The plurality of organic dye patterns 130 is formed so as to correspond to each of the plurality of sub pixels SP to have a wavelength which transmits all the red light, the green light, and the blue light. Accordingly, even though the plurality of light emitting diodes ED disposed in the plurality of sub pixels SP emits red light, green light, or blue light, the plurality of organic dye patterns 130 may transmit light emitted from each of the plurality of sub pixels SP. However, the present disclosure is not limited thereto and the plurality of organic dye patterns 130 may be formed so as to transmit different wavelengths for every sub pixel SP. For example, the organic dye pattern 130 disposed in the sub pixel SP which emits red light is configured by a wavelength which transmits red light. The organic dye pattern 130 disposed in the sub pixel SP which emits green light is configured by a wavelength which transmits green light and the organic dye pattern 130 disposed in the sub pixel SP which emits blue light is configured by a wavelength which transmits blue light. For example, when the plurality of organic dye patterns 130 is configured to have a wavelength which transmits all the red light, the green light, and the blue light, there is no need to use different dyes for every sub pixel SP so that it is advantageous in terms of the cost and the time for the manufacturing process.

As an example, bottom surfaces of the plurality of organic dye patterns 130 may be larger than top surfaces. For example, a size of the plurality of organic dye patterns 130, for example, a width of the plurality of organic dye patterns 130 may be gradually reduced from the bottom surfaces to the top surfaces. Specifically, each of the plurality of organic dye patterns 130 may have a top surface having the same width as the opening OP of the black matrix BM, a bottom surface which has a larger width than the opening OP of the black matrix BM, and a side surface which connects the top surface and the bottom surface and has a curved shape or a inclined shape. For example, the bottom surfaces of the plurality of organic dye patterns 130 may have a width which is equal to or larger than the emission area EA of the plurality of light emitting diodes ED and the top surfaces of the plurality of organic dye patterns 130 have a width smaller than that of the emission area EA of the plurality of light emitting diodes ED, without being limited thereto. Accordingly, even though the opening of the black matrix BM is smaller than the emission area EA so as to be applied to a device having a narrow viewing angle, all light emitted from the plurality of light emitting diodes ED is incident to the bottom surface of the plurality of organic dye patterns 130 having a width which is equal to or larger than that of the emission area EA. Thereafter, a part of light incident to the plurality of organic dye patterns 130 is discharged through the top surfaces of the plurality of organic dye patterns 130 and the other part of the light incident to the plurality of organic dye patterns 130 may be absorbed by the black matrix BM.

The plurality of organic dye patterns 130 and the black matrix BM may be disposed on the same plane, and for example, the plurality of black matrices BM may be disposed so as to cover curved side surfaces of the plurality of organic dye patterns 130. Specifically, the black matrix BM may be disposed so as to be fully filled in the space between the plurality of organic dye patterns 130. Accordingly, the side surface of the black matrix BM also has a curved shape or an incline shape. As an example, the curved shape of the side surface of the organic dye patterns 130 may be a part of the hemispheric shape, without being limited thereto.

In the meantime, the second protection layer 140 may be disposed so as to cover the plurality of organic dye patterns 130 and the black matrix BM. The second protection layer 140 may be configured by an organic insulating layer, without being limited thereto. Further, the step on the top layer of the display device 100 is suppressed by the second protection layer 140 to further improve the visibility of the display device 100.

In the related art, a display device with a structure in which a polarization plate was bonded to the display panel was used. However, when the polarization plate is separately attached, there is a problem in that the thickness of the display device is increased. In order to overcome this problem, a color filter is disposed in the display panel to replace the polarization layer. However, when the black matrix is formed between the plurality of sub pixels and a color filter is disposed for every sub pixel, a mask process for patterning the color filter is added, which causes a problem of the increase in a cost and a time for the manufacturing process.

Further, in order to apply a display device which applies a switchable privacy mode or a display device in which a narrow viewing angle is desirable, such as an external display of a VR device, when the opening of the black matrix is configured to be smaller than the emission area of the plurality of light emitting diodes, among light emitted from the plurality of light emitting diodes, all the light which is emitted toward the black matrix is absorbed by the black matrix. Therefore, there is a problem in that the luminous efficiency of the display device is degraded.

Therefore, in the display device 100 according to the exemplary embodiment of the present disclosure, the plurality of organic dye patterns 130 is disposed for each of the plurality of sub pixels SP by an application process, such as the inkjet to reduce the thickness of the display device 100. Further, the mask process is not performed so that the cost and the time for the manufacturing process may be reduced.

Further, in the display device 100 according to the exemplary embodiment of the present disclosure, in order to implement a narrow viewing angle, even though the size of the opening OP of the black matrix BM, for example, a width of the opening OP of the black matrix BM is smaller than a size of the emission area EA of the plurality of light emitting diodes ED, for example, a width of the emission area EA of the plurality of light emitting diodes ED, light emitted from the plurality of light emitting diodes ED may be first incident to the bottom surface of the plurality of organic dye patterns 130 having a width which is equal to or larger than a width of the emission area EA. Next, a part of light may be discharged through the top surface of the plurality of organic dye patterns 130 along a light path of incident light. Alternatively, another part of the incident light may be absorbed by the black matrix BM.

As an example, in the display device 100 according to the exemplary embodiment of the present disclosure, even though a part of light emitted from the plurality of light emitting diodes ED is directed to a direction overlapping the black matrix BM due to the shape of the plurality of organic dye patterns 130 and the black matrix BM, not all of the part of the emitted light is absorbed by the black matrix BM, but a part thereof may be emitted through the opening OP along the light path. Accordingly, the luminous efficiency of the display device 100 may be improved.

Further, in the display device 100 according to the exemplary embodiment of the present disclosure, a low-temperature black matrix BM and the black bank 116 are disposed in the non-emission area of the plurality of light emitting diodes ED to suppress light emitted from the plurality of light emitting diodes ED from being directed to the non-emission area of the plurality of light emitting diodes ED. Accordingly, even though the polarization layer is not disposed, the reflectance in the non-emission area of the plurality of light emitting diodes ED is reduced and the light leakage defect may be suppressed.

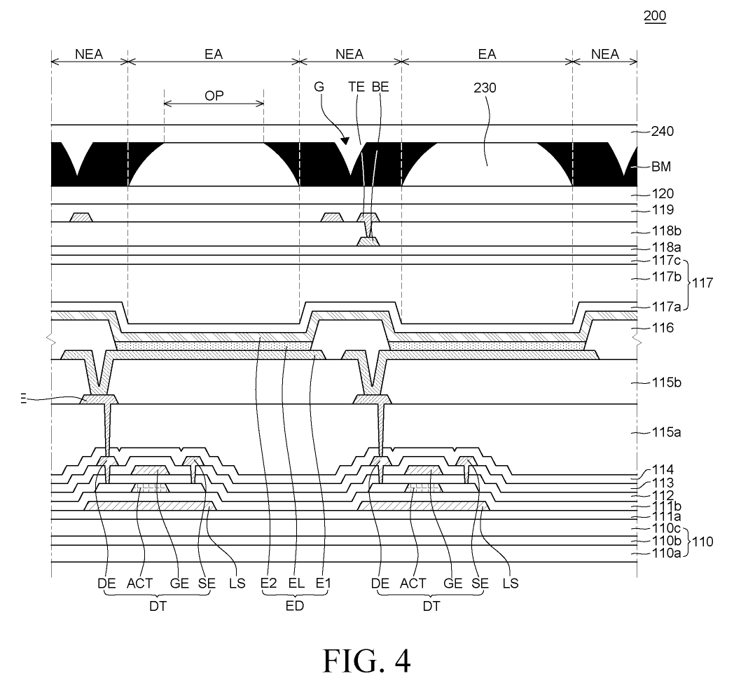

FIG. 4 is a schematic cross-sectional view of a display device according to another exemplary embodiment of the present disclosure. A display device 200 of FIG. 4 is substantially the same as the display device 100 of FIGS. 1 to 3 except for a plurality of organic dye patterns 230, a black matrix BM, and a second protection layer 240, so that a redundant description will be omitted or briefly given.

Referring to FIG. 4, in the display device 200 according to another exemplary embodiment of the present disclosure, the black matrix BM disposed in the space between the plurality of organic dye patterns 230 may include a plurality of grooves G.

When the black matrix BM includes a plurality of grooves G, heights of the plurality of organic dye patterns 230 and the black matrix BM are relatively larger than heights of the plurality of organic dye patterns 130 and the black matrix BM of FIGS. 1 to 3. Further, when the black matrix BM includes a plurality of grooves G, the opening OP of the black matrix BM may be relatively smaller than the opening OP of the black matrix BM of FIGS. 1 to 3. When the heights of the plurality of organic dye patterns 230 and the black matrix BM are relatively large and the opening OP of the black matrix BM is relatively small, the transmittance is lowered so that when the display device 200 does not emit light, the reflectance is improved to improve the black visibility. For example, the groove G of the black matrix BM may be disposed so as to overlap the bank 116.

In the meantime, the second protection layer 240 may be disposed so as to cover the plurality of organic dye patterns 230 and the black matrix BM. The second protection layer 240 may be configured by an organic insulating layer. For example, the second protection layer 240 may be disposed so as to cover the groove G of the black matrix BM. For example, the groove G of the black matrix BM may be filled with the second protection layer 240. The step on the top layer of the display device 200 is suppressed by the second protection layer 240 to improve the visibility of the display device 200.

In the display device 200 according to another exemplary embodiment of the present disclosure, the plurality of organic dye patterns 230 is disposed for each of the plurality of sub pixels SP by an application process, such as the inkjet to reduce the thickness of the display device 200. Further, the mask process is not performed so that the cost and the time for the manufacturing process may be reduced.

Further, in the display device 200 according to the exemplary embodiment of the present disclosure, in order to implement a narrow viewing angle, the opening OP of the black matrix BM is smaller than the emission area EA of the plurality of light emitting diodes ED. For example, a width of the opening OP of the black matrix BM is smaller than a width of the emission area EA of the plurality of light emitting diodes ED. In this case, even though a part of light emitted from the plurality of light emitting diodes ED is directed to a direction overlapping the black matrix BM due to the shape of the plurality of organic dye patterns 230 and the black matrix BM, not all the part of the emitted light is absorbed by the black matrix BM, but a part thereof may be emitted through the opening OP along the light path. Accordingly, the luminous efficiency of the display device 200 may be improved.

Further, in the display device 200 according to another exemplary embodiment of the present disclosure, the black matrix BM has a plurality of grooves G so that a height of the plurality of organic dye patterns 230 and the plurality of black matrices BM and a size of the opening OP of the black matrix may be adjusted. Accordingly, when the display device 200 does not emit light, the reflectance is improved to improve the black visibility.

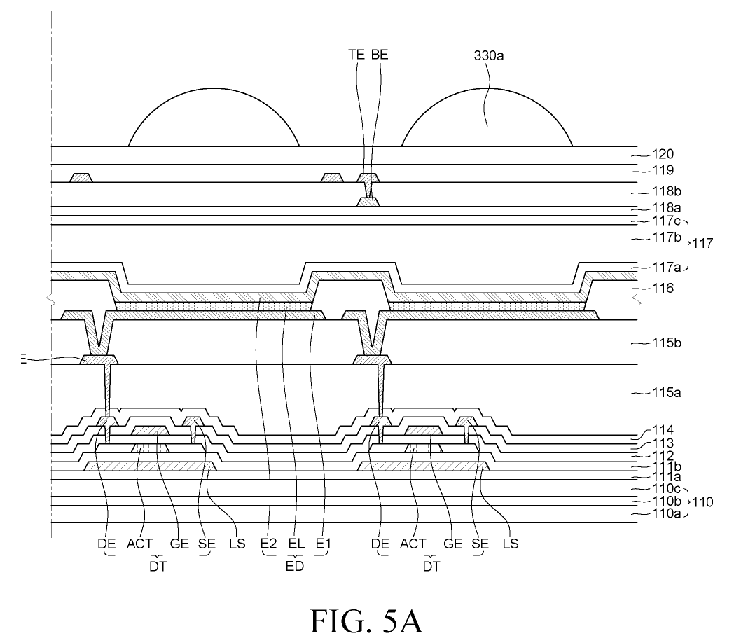

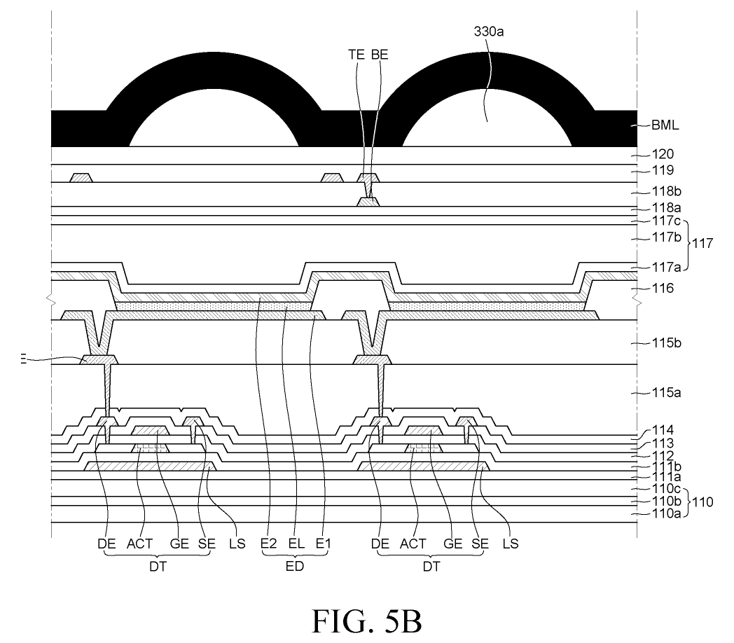

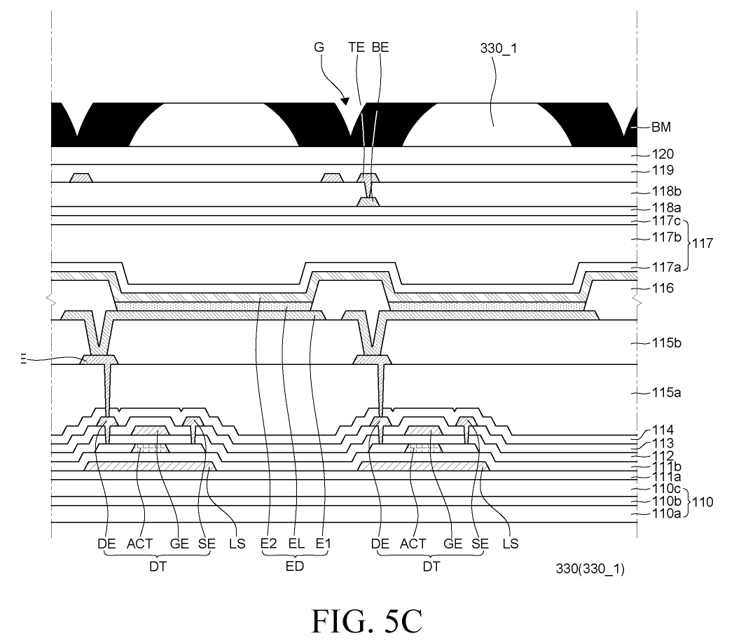

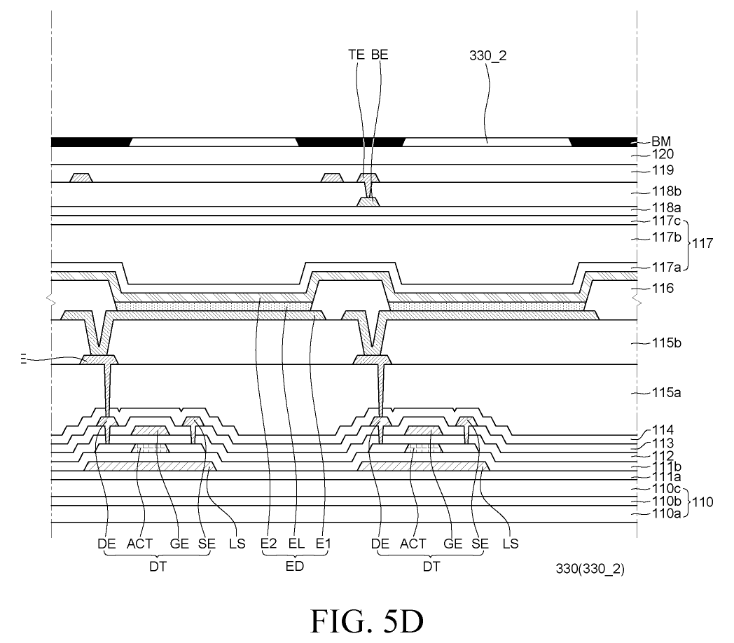

FIGS. 5A to 5D are schematic diagrams illustrating a manufacturing method of a display device according to an exemplary embodiment of the present disclosure. The manufacturing method of the display device of FIGS. 5A to 5D is a method for manufacturing the display device of FIGS. 1 to 3 or the display device of FIG. 4.

First, as illustrated in FIG. 5, a substrate 110 on which a plurality of light emitting diodes ED is disposed is prepared. On the substrate 110, an encapsulation unit 117 and a touch sensing unit are disposed so as to cover the plurality of light emitting diodes ED and a first protection layer 119 and a third buffer layer 120 may be disposed so as to cover the touch sensing unit.

A plurality of organic dyes 330a is formed on the third buffer layer 120 by an inkjet process so as to cover the emission area EA of the plurality of light emitting diodes ED. At this time, as the plurality of organic dyes 330a is ejected by the inkjet, it has a hemispheric shape, but is not limited thereto. For example, bottom surfaces of the plurality of organic dyes 330a may have a width which is equal to or larger than that of the emission area EA and a width of the top surfaces of the plurality of organic dyes 330a may be smaller than the width of the emission area EA.

Next, as illustrated in FIG. 5B, the black matrix layer BML may be coated so as to cover the plurality of organic dyes 330a.

Next, as illustrated in FIG. 5C, the plurality of organic dyes 330a and the black matrix layer BML are polished by means of a chemical mechanical polishing (CMP) process to form a plurality of organic dye patterns 330 and a black matrix BM. For example, a polishing pad is located above the plurality of organic dyes 330a and the black matrix layer BML and a pressure and a speed are applied while supplying slurry between the plurality of organic dyes 330a and the black matrix layer BML and the polishing pad to polish the plurality of organic dyes 330a and the black matrix layer BML.

At this time, the heights of the plurality of organic dye patterns 330 and the black matrix BM and the opening OP of the black matrix BM, for example, the width of the opening OP of the black matrix BM may be adjusted depending on a polished amount. For example, when the polished amount is small, as illustrated in FIGS. 4 and 5C, the heights of the plurality of organic dye patterns 330_1 and the black matrix BM are relatively large and the opening OP of the black matrix BM is relatively small. For example, as illustrated in FIGS. 4 and 5C, the heights of the plurality of organic dye patterns 330_1 and the black matrix BM are relatively high and the width of the opening OP of the black matrix BM is relatively small, and the transmittance of the display device is relatively lowered. Accordingly, when the display device does not emit light, the reflectance is improved to improve the black visibility. Further, the polished amount is relatively small so that the manufacturing process time is shortened and damages, such as scratches, on the top surface of the display device may be reduced. As an example, when the polished amount is small, as illustrated in FIGS. 4 and 5C, the flat portion or the groove G may remain between adjacent organic dyes 330a. Otherwise, when the polished amount is increased, the groove G may be removed completely such that the black matrix BM may have a flat top surface between adjacent organic dyes 330a.

Next, when the polished amount is increased more than that in FIG. 5C, as illustrated in FIG. 5D, the heights of a plurality of organic dye patterns 330_2 and the black matrix BM may be relatively low and the opening OP of the black matrix BM may be relatively large. For example, if the heights of the plurality of organic dye patterns 330_2 and the black matrix BM are relatively low and the opening OP of the black matrix BM is relatively large, the transmittance of the display device is improved to reduce the power consumption.

For example, the polished amount of the plurality of organic dye patterns 330 and the black matrix BM may be adjusted by changing a pressure between the plurality of organic dyes 330a and the black matrix layer BML and the polishing pad, a rotation speed of the polishing pad, or a polishing time.

During the polishing process of the plurality of organic dyes 330a and the black matrix layer BML according to the exemplary embodiment of the present disclosure, the polished amount of the plurality of organic dyes 330a and the black matrix layer BML is adjusted to adjust the transmittance and the reflectance of the display device.

The exemplary embodiments of the present disclosure can also be described as follows:

According to an aspect of the present disclosure, a display device, including a substrate including an active area in which a plurality of sub pixels is disposed and a non-active area which encloses the active area, a plurality of light emitting diodes disposed in the plurality of sub pixels on the substrate, an encapsulation unit which is disposed so as to cover the plurality of light emitting diodes, a touch sensing unit which is disposed on the encapsulation unit and includes a plurality of touch electrodes, a plurality of organic dye patterns which is disposed on the touch sensing unit so as to overlap emission areas of the plurality of light emitting diodes and has bottom surfaces larger than top surfaces, and a black matrix which exposes the top surfaces of the plurality of organic dye patterns.

The bottom surfaces of the plurality of organic dye patterns may be equal to or larger than the emission areas of the plurality of light emitting diodes and the top surfaces of the plurality of organic dye patterns may be smaller than the emission areas of the plurality of light emitting diodes.

Side surfaces of the plurality of organic dye patterns may have a curved shape.

The black matrix may be disposed so as to cover the side surfaces of the plurality of organic dye patterns.

The plurality of organic dye patterns and the black matrix may be located on the same plane.

The black matrix may be fully filled in a space between the plurality of organic dye patterns.

The black matrix disposed in the space between the plurality of organic dye patterns may include a groove.

The display device may further including a bank which is disposed so as to cover ends of first electrodes of the plurality of light emitting diodes to define an emission area, the groove of the black matrix may be disposed so as to overlap the bank.

The display device may further including a protection layer which covers the black matrix and the plurality of organic dye patterns, the protection layer may be disposed so as to cover the groove of the black matrix.

According to another aspect of the present disclosure, a display device including a substrate, a plurality of light emitting diodes disposed on the substrate, an encapsulation unit which is disposed so as to cover the plurality of light emitting diodes, a touch sensing unit which is disposed on the encapsulation unit and includes a plurality of touch electrodes, a black matrix which is disposed on the touch sensing unit and includes opening overlapping emission areas of the plurality of light emitting diodes, and a plurality of organic dye patterns which is disposed between the black matrices and has bottom surfaces larger than the opening of the black matrix, top surfaces having the same size as the opening of the black matrix, and side surfaces which connect the top surfaces and the bottom surfaces and have a curved shape.

The black matrix may be disposed so as to cover the side surfaces of the plurality of organic dye patterns.

The plurality of organic dye patterns and the black matrix may be located on the same plane.

The black matrix may be fully filled in a space between the plurality of organic dye patterns.

The black matrix disposed in the space between the plurality of organic dye patterns may include a groove.

The display device may further including a bank which is disposed so as to cover ends of first electrodes of the plurality of light emitting diodes to define the emission areas, the groove of the black matrix may be disposed so as to overlap the bank.

The display device may further including a protection layer which covers the black matrix and the plurality of organic dye patterns, the protection layer may be disposed so as to cover the groove of the black matrix.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate on which a plurality of sub pixels is disposed;
a plurality of light emitting diodes disposed in the plurality of sub pixels on the substrate;
an encapsulation unit covering the plurality of light emitting diodes; and
a plurality of organic dye patterns covering the encapsulation unit so as to overlap emission areas of the plurality of light emitting diodes and has bottom surfaces larger than top surfaces.

2. The display device according to claim 1, further comprising:
a black matrix configured to expose the top surfaces of the plurality of organic dye patterns.

3. The display device according to claim 1, wherein the bottom surfaces of the plurality of organic dye patterns are equal to or larger than the emission areas of the plurality of light emitting diodes and the top surfaces of the plurality of organic dye patterns are smaller than the emission areas of the plurality of light emitting diodes.

4. The display device according to claim 1, wherein side surfaces of the plurality of organic dye patterns have a curved shape.

5. The display device according to claim 4, wherein the black matrix covering side surfaces of the plurality of organic dye patterns.

6. The display device according to claim 5, wherein the plurality of organic dye patterns and the black matrix are located on the same plane.

7. The display device according to claim 6, wherein the black matrix is fully filled in a space between the plurality of organic dye patterns.

8. The display device according to claim 6, wherein the black matrix disposed in the space between the plurality of organic dye patterns has at least one groove.

9. The display device according to claim 8, further comprising:
a bank covering ends of first electrodes of the plurality of light emitting diodes to define an emission area,
wherein the groove of the black matrix is disposed so as to overlap the bank.

10. The display device according to claim 8, further comprising:
a protection layer covering the black matrix and the plurality of organic dye patterns,
wherein the protection layer covers the groove of the black matrix.

11. The display device according to claim 2, wherein the plurality of organic dye patterns and the black matrix have the same thickness, such that a top surface of the plurality of organic dye patterns is aligned with a top surface of the black matrix.

12. The display device according to claim 1, wherein the plurality of organic dye patterns is configured to transmit all of a red light, a green light, and a blue light.

13. The display device according to claim 1, further comprising:
a touch sensing unit disposed on the encapsulation unit and including a plurality of touch electrodes,
wherein the plurality of organic dye patterns is disposed on the touch sensing unit.

14. A display device, comprising:
a substrate;
a plurality of light emitting diodes disposed on the substrate;
an encapsulation unit covering the plurality of light emitting diodes;
a black matrix covering the encapsulation unit and including an opening overlapping emission areas of the plurality of light emitting diodes; and
a plurality of organic dye patterns which is disposed between the black matrices and has bottom surfaces larger than the opening of the black matrix, top surfaces having the same size as the opening of the black matrix, and side surfaces which connect the top surfaces and the bottom surfaces and have a curved shape.

15. The display device according to claim 14, wherein the black matrix covers the side surfaces of the plurality of organic dye patterns.

16. The display device according to claim 15, wherein the plurality of organic dye patterns and the black matrix are located on the same plane.

17. The display device according to claim 16, wherein the black matrix is fully filled in a space between the plurality of organic dye patterns.

18. The display device according to claim 16, wherein the black matrix disposed in the space between the plurality of organic dye patterns includes at least one groove.

19. The display device according to claim 18, further comprising:
a bank covering ends of first electrodes of the plurality of light emitting diodes to define the emission areas,
wherein the at least one groove of the black matrix is disposed so as to overlap the bank.

20. The display device according to claim 18, further comprising:
a protection layer covering the black matrix and the plurality of organic dye patterns,
wherein the protection layer covers the at least one groove of the black matrix.
